(19) United States
(12) Patent Application Publication
(10) Pub. No.: US 2023/0088567 A1
(43) Pub. Date: Mar. 23, 2023

(54) ELECTRIC FIELD-VIBRATION GENERATING TRANSDUCER HAVING PIEZOELECTRIC MATERIAL OF HIGH DEGREE OF DISPLACEMENT, AND MANUFACTURING METHOD THEREOF

(71) Applicant: CERACOMP CO., LTD., Asan-si (KR)

(72) Inventors: Ho Yong LEE, Seoul (KR); Won Sun BAICK, Seoul (KR); Dong Ho KIM, Seoul (KR); Moon Chan KIM, Seoul (KR)

(21) Appl. No.: 18/071,535

(22) Filed: Nov. 29, 2022

Related U.S. Application Data
(63) Continuation of application No. PCT/KR2022/008824, filed on Jun. 22, 2022.

(30) Foreign Application Priority Data
Aug. 10, 2021 (KR) 10-2021-0105459

(51) Int. Cl. A61H 23/02; B06B 1/06

(52) U.S. Cl. CPC H01L 41/183; A61H 23/0245; H01L 41/37; B06B 1/0662; B06B 2201/76; A61H 2201/10

(57) ABSTRACT

Provided is an electric field-vibration generating transducer having a piezoelectric material of a high degree of displacement, and a manufacturing method thereof. The electric field-vibration generating transducer lowers the cost of production through miniaturization simultaneously with realizing excellent generating characteristics of the electric field-vibration generating transducer based on high efficiency and low voltage driving because the piezoelectric material of the high degree of displacement (high strain piezoelectrics) having a high piezoelectric constant (d₃₃=1,000 to 6,000 pC/N), a high dielectric constant (K₃^{T}=6,000 to 15,000) as well as a low dielectric loss (tan δ<2%) is applied thereto, so the electric field-vibration generating transducer may accelerate the movement of a material, a chemical action, and a biological reaction, and may be applied to a medical device for the purpose of treatment for tumors aimed at human bodies and animals.

### TECHNICAL FIELD

The present invention relates to an Electric Field-Vibration Generating (EFVG) transducer, and a method of manufacturing the same, and more particularly, to an electric field-vibration generating transducer that can generate an electric field and a mechanical vibration simultaneously by the application of a piezoelectric material of a high degree of displacement (high strain piezoelectrics) having a high piezoelectric constant (d₃₃=1,000 to 6,000 pC/N), and a high dielectric constant (K₃^{T}=6,000 to 15,000) as well as a low dielectric loss (tan δ<2%), can accelerate the movement of a material, a chemical action, and a biological reaction using the electric field and the mechanical vibration as generated above, and can be applied to a medical device for the purpose of treatment for tumors aimed at human bodies and animals, and to a method of manufacturing the electric field-vibration generating transducer.

### BACKGROUND ART

Electric field emission can be realized in such a manner as to use a metal cable, or by a method of causing voltage to be applied to a dielectric. In particular, the method of generating the electric field by directly applying the voltage to the dielectric is more effective than the method of using a general metal plate, and so on with respect to the generating of the electric field.

Specifically, in case that a dielectric is located between two metal plates, density of an electric field between said two metal plates increases due to a polarization phenomenon of the dielectric, whereas when a gap between said two metal plates is a vacuum, the density of the electric field between said two metal plates is proportional to voltage applied simply due to the absence of a polarization phenomenon.

Accordingly, when the polarization phenomenon of the dielectric is used, the electric field between said two metal plates increases, and as a result, generating of the larger electric field becomes possible. The generating of such an electric field has been utilized in a field intended for controlling various phenomena, like the movement of a material, a chemical action, a biological reaction, and so on, and has been expected to be applied to medical devices, and so on more extensively for the future.

In general, an electric field generating transducer using a dielectric comprises a dielectric element; an external electrode configured to cause an electric field to be applied to the dielectric element; and a voltage supply device configured to cause voltage to be applied to the external electrode. The dielectric element is electrically connected to the external electrode, and the external electrode is connected to the voltage supply device so that an electrical signal is applied to the dielectric device. At this time, magnitude of the electric field radiated from the electric field generating transducer is generally proportional to magnitude of the applied voltage, and a dielectric constant of the dielectric. Accordingly, when a raw material whose dielectric constant is large is used, the magnitude of the electric field radiated can increase.

In general, polycrystalline ceramic materials based on BaTiO₃, Pb(Zr, Ti)O₃ (hereinafter referred to as “PZT”), Pb(Mg_{1/3}Nb_{2/3})O₃ (hereinafter referred to as “PMN”), and Pb(Mg_{1/3}Nb_{2/3})O₃—PbTiO₃ (hereinafter referred to as “PMN-PT”) which are ferroelectrics among dielectric ceramic materials have mainly been used. The polycrystalline ceramic materials based on BaTiO₃, PZT, PMN, and PMN-PT are materials which have a large dielectric constant and are low in prices, and manufacturing process techniques for which have been well-known, and they have been used in various applied fields.

However, with respect to dielectrics and/or ferroelectrics of the polycrystalline ceramic materials based on BaTiO₃, PZT, PMN, and PMN-PT which have currently been used, it is disadvantageous in that a dielectric constant is 5,000 or below, and a dielectric loss tan δ exceeds 2.0%. At this time, when the dielectric loss is large, in case that voltage is applied, particularly, in case that alternating current voltage is applied, the generation of heat is large, and a lowering in physical property of the dielectrics is induced, and as a result, efficiency of the electric field generating transducer gets low.

Also, the heat generation makes a chemical action or a biological reaction for changing and controlling surrounding temperatures difficult to be accomplished.

Due to this limit of dielectric ceramic materials, the electric field generating transducer is restricted in performance, and due to large power consumption, a size of the total system increases, so it is difficult to manufacture portable products.

Accordingly, since performance of the electric field generating transducer is decided by that of the dielectric, it has been required to develop a dielectric or ferroelectric material having a low dielectric loss simultaneously with a high dielectric constant.

As a part of this, piezoelectric single crystals having a perovskite crystal structure ([A][B]O₃) have been suggested as materials that show characteristics of a remarkably low dielectric loss simultaneously with a remarkably high dielectric constant K₃^{T} and a remarkably high piezoelectric constant d₃₃ beyond those shown in conventional piezoelectric polycrystalline ceramic materials, and a possibility of development of electric field generating transducers using them has been presented.

Examples of the piezoelectric single crystals having the perovskite type crystal structure include PMN-PT (Pb(Mg_{1/3}Nb_{2/3})O₃—PbTiO₃) PZN-PT (Pb(Zn_{1/3}Nb_{2/3})O₃—PbTiO₃), PInN-PT (Pb(In_{1/2}Nb_{1/2})O₃—PbTiO₃) PYbN-PT (Pb (Yb_{1/2}Nb_{1/2})O₃—PbTiO₃), PSN-PT (Pb(Sc_{1/2}Nb_{1/2})O₃—PbTiO₃) PMN-PInN-PT, PMN-PYbN-PT, BiScO₃—PbTiO₃(BS-PT), and so on. Since these piezoelectric single crystals show a congruent melting behavior at the time of melting, they have been manufactured by a flux method, Bridgman method, and so on.

In general, the piezoelectric single crystals having the perovskite type crystal structure have been known as showing the highest dielectric and piezoelectric characteristics from a neighboring area with respect to composition in a morphotropic phase boundary (i.e., MPB) between a rhombohedral phase and a tetragonal phase.

However, since the piezoelectric single crystals having the perovskite type crystal structure show the best excellent dielectric and piezoelectric characteristics when they are generally in a rhombohedral phase, the piezoelectric single crystals in the rhombohedral phase have most actively been utilized in their application, but since the piezoelectric single crystals in the rhombohedral phase are stable only at a phase transition temperature T_{RT} or below between the rhombohedral phase and a tetragonal phase, they can be used only at the phase transition temperature T_{RT}, the maximum temperature, which enables the rhombohedral phase to be stable, or below. Accordingly, in case that the phase transition temperature T_{RT} is low, workable temperature of the piezoelectric single crystals in the rhombohedral phase gets low, and temperature required for manufacturing components to which the piezoelectric single crystals are applied, and workable temperature are also limited to the phase transition temperature T_{RT} or below. At this time, in case that phase transition temperatures T_{C} and T_{RT}, and a coercive electric field E_{C} are low, the piezoelectric single crystals show that poling is easily removed (depoling) under the conditions of mechanical processing, a stress, the generation of heat, and driving voltage, and the loss of excellent dielectric and piezoelectric characteristics occurs.

Also, although the piezoelectric single crystals show a high piezoelectric constant (d₃₃≥1,000 to 2,000 pC/N) compared with that shown in piezoelectric polycrystalline ceramic materials, since a coercive electric field is low (E_{C}≤2 to 5 kV/cm), depoling easily occurs, and accordingly, the piezoelectric single crystals are restricted in their practical use because electrical stability is low. Thus, although a method of raising the coercive electric field of the piezoelectric single crystals has been suggested, since it is problematic in that an increase in the coercive electric field is attended with a decline in piezoelectric characteristic, low effectiveness of the method has still been pointed.

Accordingly, steady studies of piezoelectric single crystals have currently been carried out in order to simultaneously improve a dielectric constant, a piezoelectric constant, phase transition temperatures, a coercive electric field, a mechanical characteristic, and so on, and in particular, with respect to piezoelectric single crystals of composition including a costly element, like Sc, In, and so on, as a main ingredient, the high cost of production for the single crystals has been a substantial obstacle to practical use of single crystals.

Patent Document 1 discloses an invention relating to a solid-state single crystal growth [SSCG] method, unlike a conventional liquid phase single crystal growth method, the method doesn't use a melting process, wherein single crystals of various kinds of composition may be manufactured by the solid-state single crystal growth method that is carried out in such a manner as to control the growth of abnormal grains occurring from a polycrystal through a general simple heat treatment process without a special device, so the single crystal growth method capable of reducing the cost of production for the single crystals, and manufacturing the single crystals on a massive scale thanks to high reproducibility and economic efficiency has been suggested.

Also, Patent Document 2 discloses a piezoelectric single crystal having high piezoelectric constants d₃₃ and k₃₃, a high phase transition temperature (a curie temperature T_{c}), a high coercive electric field E_{C}, and an improved mechanical characteristic simultaneously using a solid phase single crystal growth method, and with respect to the piezoelectric single crystal manufactured by the appropriate solid phase state single crystal growth method to mass production of the single crystal, it is possible to commercialize the piezoelectric single crystal by the development of composition of the single crystal in which a costly raw material is not included, and piezoelectric and dielectric application components using the piezoelectric single crystal having the excellent characteristics can be manufactured and used in a wide temperature area.

Thus, as a result of the present inventors' efforts for improving performance of electric field generating transducers, the present invention has been completed in such a manner as to simultaneously generate a mechanical vibration as well as an electric field by applying a piezoelectric material of a high degree of displacement (high strain piezoelectrics) having a low dielectric loss simultaneously with a high dielectric constant K₃^{T}, and high piezoelectric constants d₃₃ and k₃₃, and to enable the development of a novel electric field-vibration generating transducer using the generated electric field and mechanical vibration, and to confirm characteristics of high efficiency and low voltage driving, and the generation of low heat.
(Patent Document 1) Korean Patent No. 0564092 (officially announced on Mar. 27, 2006)
(Patent Document 2) Korean Patent No. 0743614 (officially announced on Jul. 30, 2007)

### DETAILED DESCRIPTION OF THE INVENTION

### Technical Problem

An object of the present invention is to provide an electric field-vibration generating transducer capable of radiating and controlling an electric field and a mechanical vibration simultaneously.

The other object of the present invention is to provide a method of manufacturing an electric field-vibration generating transducer using a piezoelectric single crystal which is a piezoelectric material of a high degree of displacement, or using a polymer-piezoelectric composite comprising the piezoelectric single crystal.

### Solution for Solving the Problem

In order to accomplish the objects described above, the present invention provides an electric field-vibration generating transducer, which radiates an electric field and a mechanical vibration simultaneously, comprising: a piezoelectric material having a perovskite type crystal structure ([A][B]O₃); and an electrode formed on at least one surface of the piezoelectric material, wherein it is satisfied that a piezoelectric constant d₃₃ of the piezoelectric material is 1,000 to 6,000 pC/N, a dielectric constant K₃^{T} of the piezoelectric material is 6,000 to 15,000, and a dielectric loss of the piezoelectric material is 2% or below.

With respect to the electric field-vibration generating transducer of the present invention, when the electrode is formed only on any one surface of the piezoelectric material, or the electrode is formed only on both surfaces of the piezoelectric material, it is characteristic in that the electrode is formed asymmetrically in such a manner to vary each electrode with respect to a material, a shape, or an area thereof. At this time, the electrode is any one selected from a group consisting of conductive metal, carbon, and conductive ceramic.

With respect to the electric field-vibration generating transducer of the present invention, a piezoelectric single crystal, or a polymer-piezoelectric composite comprising the piezoelectric single crystal is used in the piezoelectric material.

In the above fact, the piezoelectric single crystal is a piezoelectric single crystal grown by a solid phase single crystal growth method, and more specifically, a piezoelectric single crystal expressed by a compositional formula of Chemical Formula 1 below:

[A_{1-(a+1.5b)}BₐC_{b}][(MN)_{1-x-y}(L)_{y}Tiₓ]O_{3-z} Chemical Formula 1

in said formula,

A represents one or more elements selected from a group consisting of Pb, Sr, Ba, and Bi

B represents at least one or more elements selected from a group consisting of Ba, Ca, Co, Fe, Ni, Sn, and Sr,

C represents one or more elements selected from a group consisting of Co, Fe, Bi, La, Ce, Pr, Nd, Pm, Sm, Eu, Gd, Tb, Dy, Ho, Er, Tm, Yb, and Lu,

L represents a single form composed of one selected from Zr or Hf, or a mixed form thereof,

M represents at least one or more elements selected from a group consisting of Ce, Co, Fe, In, Mg, Mn, Ni, Sc, Yb, and Zn,

N represents at least one or more elements selected from a group consisting of Nb, Sb, Ta, and W, and

a, b, x, y, and z represent 0≤a≤0.10, 0≤b≤0.05, 0.05≤x≤0.58, 0.05≤y≤0.62, and 0≤z≤0.02, respectively.

With respect to the piezoelectric single crystal, in said formula, a requisite of 0.01≤a≤0.10, and a requisite of 0.01≤b≤0.05 are satisfied, and in particular, in said formula, a requisite of a/b≥2 is satisfied.

Also, with respect to the piezoelectric single crystal, it is preferable that in said formula, a requisite of 0.10≤x≤0.58, and a requisite of 0.10≤y≤0.62 are satisfied.

With respect to the piezoelectric single crystal, when L represents a mixed form, the piezoelectric single crystal is expressed by a compositional formula of Chemical Formula 2 or Chemical Formula 3 below:

[A_{1-(a+1.5b)}BₐC_{b}][(MN)_{1-x-y}(Zr_{1-w},Hf_{w})_{y}Tiₓ]O₃ Chemical Formula 2

[A_{1-(a+1.5b)}BₐC_{b}][(MN)_{1-x-y}(Zr_{1-w},Hf_{w})_{y}Tiₓ]O_{3-z} Chemical Formula 3

in said formulae, A, B, C, M, N, a, b, x, y, and z are the same as those shown in said Chemical Formula 1, but w represents 0.01≤w≤0.20.

According to the present invention, a 0.1 to 20% reinforced second phase P may further be included in the composition of the piezoelectric single crystal at a volume ratio, and the reinforced second phase may be a metal phase, an oxide phase, or pores.

The reinforced second phase P is at least one or more materials selected from a group consisting of Au, Ag, Ir, Pt, Pd, Rh, MgO, ZrO₂, and a pore, and the reinforced second phase P is uniformly distributed in a particle form inside of the piezoelectric single crystal, or the reinforced second phase is regularly distributed while having a fixed pattern.

Also, with respect to the electric field-vibration generating transducer of the present invention, a polymer-piezoelectric composite is used in the piezoelectric material so that flexibility can be provided.

With respect to the polymer-piezoelectric composite, a piezoelectric polycrystal or a piezoelectric single crystal may be included in a polymer matrix, and specifically, the polymer matrix is comprising a range of 10 to 80 vol %.

Specifically, the polymer-piezoelectric composite is a 1-3 type or 2-2 type composite structure in which a rod-type piezoelectric material is embedded in the polymer matrix, wherein the piezoelectric composite results from mixing the piezoelectric polycrystalline ceramic into the piezoelectric single crystal.

The electric field-vibration generating transducer described above shows that a frequency of the electric field radiated is 0.01 Hz to 500 kHz, and intensity of the electric field is 0.01 to 100 V/cm.

Also, a frequency of the mechanical vibration radiated is 0.1 Hz to 3 MHz, and magnitude of the mechanical vibration is a maximum of 1%.

Also, with respect to the electric field-vibration generating transducer of the present invention, the piezoelectric material shows that surface unevenness may be formed on its surface by pores, or grooves (grooves or a channel, or the like).

Furthermore, with respect to a method of manufacturing an electric field-vibration generating transducer, the present invention provides the manufacturing method of the electric field-vibration generating transducer, comprising of: processing a piezoelectric material having a perovskite type crystal structure ([A][B]O₃) of claim 1 in a thickness of 0.1 to 100 mm; forming each external electrode on both surfaces of the piezoelectric material; carrying out poling by causing voltage to be applied to said each external electrode, thereby maximizing dielectric and piezoelectric characteristics of the piezoelectric material; and partly or totally removing any one of the external electrodes formed on both surfaces, thereby forming an asymmetric structure.

In the above fact, the piezoelectric material is a piezoelectric single crystal having a perovskite type crystal structure ([A][B]O₃) or a polymer-piezoelectric composite comprising the piezoelectric single crystal.

### Effect of the Invention

Since the electric field-vibration generating transducer according to the present invention comprises a piezoelectric material of a high degree of displacement having a low dielectric loss (tan δ<2%) simultaneously with a high piezoelectric constant (d₃₃=1,000 to 6,000 pC/N), a high dielectric constant (K₃^{T}=6,000 to 15,000), the electric field-vibration generating transducer capable of maintaining the high characteristics, and generating an electric field and a mechanical vibration simultaneously can be provided.

Since the piezoelectric single crystal having a piezoelectric characteristic used in the present invention shows that a high dielectric constant, and a high piezoelectric constant are maintained thanks to the solid phase single crystal growth method, and enables mass production at a low process cost, when it is used in the present invention, the movement of a material, a chemical action, and a biological reaction can be accelerated, and a medical device for the purpose of treatment for tumors aimed at human bodies and animals can be satisfied with respect to the improvement of performance thereof, and competitiveness in price.

### BRIEF DESCRIPTION OF THE DRAWINGS

FIG. 1 is a cross-sectional schematic diagram showing an electric field-vibration generating transducer according to the present invention,

FIG. 2 illustrates a case in which the electric field-vibration generating transducer according to the present invention is applied into a medical device,

FIG. 3 shows a result of evaluating bending concerning a polymer-piezoelectric composite according to the present invention,

FIG. 4 is a schematic diagram showing a structure of the polymer-piezoelectric composite,

FIG. 5 shows images concerning a 1-3 type composite structure,

FIG. 6 illustrates, by steps, a manufacturing process of an electric field-vibration generating transducer using the polymer-piezoelectric composite,

FIG. 7 illustrates intensity of an induced electric field resulting from causing voltage to be applied to an electric field-vibration generating transducer using a piezoelectric single crystal of composition of [Pb_{0.965}Sr_{0.02}La_{0.01}][(Mg_{1/3}Nb_{2/3})_{0.4}Zr_{0.25}Ti_{0.35}]O₃,

FIG. 8 illustrates magnitude of a mechanical vibration resulting from causing the voltage to be applied to the electric field-vibration generating transducer shown in FIG. 7,

FIG. 9 illustrates intensity of an induced electric field resulting from causing voltage to be applied to an electric field-vibration generating transducer using a piezoelectric single crystal of composition of [Pb_{0.965}Sr_{0.02}Sm_{0.01}][(Mg_{1/3}Nb_{2/3})_{0.25}(Ni_{1/3}Nb_{2/3})_{0.10}Zr_{0.30}Ti_{0.35}]O₃, and

FIG. 10 illustrates magnitude of a mechanical vibration resulting from causing the voltage to be applied to the electric field-vibration generating transducer shown in FIG. 9.

### BEST MODE FOR CARRYING OUT THE INVENTION

Hereinafter, the present invention is described in detail.

The present invention provides an electric field-vibration generating transducer comprising a piezoelectric material having a perovskite type crystal structure ([A][B]O₃), and an electrode formed on at least one surface of the piezoelectric material.

With respect to the electric field-vibration generating transducer, the piezoelectric material is a piezoelectric material of a high degree of displacement which satisfies that (1) a piezoelectric charge constant d₃₃ is 1,000 to 6,000 pC/N, (2) a dielectric constant K₃^{T} is 6,000 to 15,000, and (3) a dielectric loss is 2% or below, the electric field-vibration generating transducer may be manufactured in such a manner as to radiate an electric field and a mechanical vibration simultaneously at the time of causing voltage to be applied, and the electric field-vibration generating transducer capable of simultaneously controlling each frequency, each magnitude, and each direction of the electric field and the mechanical vibration radiated may be provided.

The frequency of the electric field radiated is 0.01 Hz to 500 kHz, and intensity of the electric field is 0.01 to 100 V/cm.

Also, the frequency of the mechanical vibration radiated is 0.1 Hz to 3 MHz, and the magnitude of the mechanical vibration is a maximum of 1%.

With respect to the electric field-vibration generating transducer according to the present invention, when the electrode is formed only on any one surface of the piezoelectric material, or when the electrode is formed on both surfaces, it is formed asymmetrically in such a manner as to vary each electrode with respect to a material, a shape, or an area. At this time, the electrode may be any one selected from a group consisting of conductive metal, carbon, and conductive ceramic.

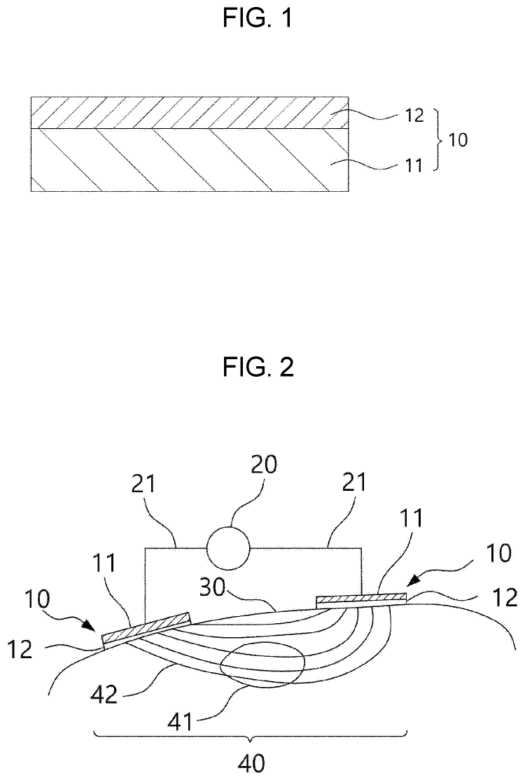

FIG. 1 represents a cross-sectional schematic diagram showing an electric field-vibration generating transducer according to the present invention, according to a preferable exemplary embodiment, the electric field-vibration generating transducer 10 has an asymmetrical structure in which an electrode 12 is formed only on one surface of a piezoelectric material 11, and in case that the electric field-vibration generating transducer is applied into a medical device, it provides an effect of medical treatment for a target tumor in such a manner as to radiate an electric field and a mechanical vibration simultaneously at the time of causing voltage to be applied by making the surface of the piezoelectric material 11 come into direct contact with the skin.

It is preferable to make surface unevenness by artificially forming pores or grooves (grooves or a channel, or the like) on the surface of the piezoelectric material, and making of the surface unevenness may be carried out in such a manner as to use the pores inside of the piezoelectric material, or to select one or more kinds of processing from various kinds of mechanical and chemical processing. A shape of the surface unevenness of the piezoelectric material has an effect on distribution of the electric field and the vibration locally. The local distribution of the electric field and the vibration may be controlled by a change in the shape of the surface unevenness, and the effect may be maximized.

With respect to the electric field-vibration generating transducer according to the present invention, since polycrystalline ceramic materials based on BaTiO₃, PZT, PMN, and PMN-PT, which are piezoelectric materials, show that a piezoelectric constant d₃₃ is 600 pC/N or below, so displacement increases proportionally from low applied voltage, but show a nonlinear behavior in which the displacement does not increase any longer at specific applied voltage (or an electric field) or more, so the maximum displacement generally becomes 0.3% or below. Accordingly, in case that the polycrystalline ceramic material is used alone, even a maximum of 1% displacement may not occur at permissible voltage or below for each applied component, so it is difficult to generate a sufficient mechanical vibration for practical application.

In particular, with respect to the electric field-vibration generating transducer, due to its structure in which the electrode is formed only on one surface of a dielectric, magnitude of the mechanical vibration which may be generated decreases more. Accordingly, it is excluded that the polycrystalline ceramic materials based on BaTiO3, PZT, PMN, and PMN-PT which are piezoelectric materials with respect to the electric field-vibration generating transducer according to the present invention are used individually.

Also, in case of general dielectric ceramic having a high dielectric constant, since a dielectric loss is large, when alternating current voltage is applied, the generation of heat is large, and as a result, efficiency of the electric field-vibration generating transducer gets low, so the worth of practical application is low.

Based on the above fact, with respect to the electric field-vibration generating transducer according to the present invention, it is necessarily required for the piezoelectric materials to satisfy requisites as follows: (1) a piezoelectric constant d₃₃ of the piezoelectric material is 1,000 to 6,000 pC/N; and (2) a dielectric constant K₃^{T} of the piezoelectric material is 6,000 to 15,000 so that dielectric and piezoelectric characteristics are excellent; and at the time as this, (3) a dielectric loss of the piezoelectric material is 2% or below, and is low, and as the piezoelectric material of a high degree of displacement which satisfies the requisites is applied, a novel electric field-vibration generating transducer having characteristics of high efficiency and low voltage driving, and low heat generation may be embodied.

The piezoelectric material used in the electric field-vibration generating transducer is a piezoelectric single crystal having a perovskite type crystal structure ([A][B]O₃), or a polymer-piezoelectric composite comprising the piezoelectric single crystal, and in case of the piezoelectric single crystal, displacement (or vibration) increases proportionally according an increase in applied voltage, so a maximum of 1% displacement may be realized.

Hereinafter, the electric field-vibration generating transducer according to the present invention is described in detail according to each material.

(1) Piezoelectric Single Crystal

A piezoelectric single crystal used in the electric field-vibration generating transducer according to the present invention is a piezoelectric material satisfying piezoelectric characteristics which simultaneously show that (1) a piezoelectric constant d₃₃ is 1,000 to 6,000 pC/N, (2) a dielectric constant K₃^{T} is 6,000 to 15,000, and (3) a dielectric loss is 2% or below.

The piezoelectric single crystal which satisfies these characteristics is a piezoelectric single crystal grown by a solid phase single crystal growth method, and more specifically, a piezoelectric single crystal represented by a compositional formula having a perovskite type structure ([A][B]O₃) of Chemical Formula 1 below:

[A_{1-(a+1.5b)}BₐC_{b}][(MN)_{1-x-y}(L)_{y}Tiₓ]O_{3-z} Chemical Formula 1

in said formula,

A represents one or more elements selected from a group consisting of Pb, Sr, Ba, and Bi,

B represents at least one or more elements selected from a group consisting of Ba, Ca, Co, Fe, Ni, Sn, and Sr,

C represents one or more elements selected from a group consisting of Co, Fe, Bi, La, Ce, Pr, Nd, Pm, Sm, Eu, Gd, Tb, Dy, Ho, Er, Tm, Yb, and Lu,

L represents a single form composed of one selected from Zr or Hf, or a mixed form thereof,

M represents at least one or more elements selected from a group consisting of Ce, Co, Fe, In, Mg, Mn, Ni, Sc, Yb, and Zn

N represents at least one or more elements selected from a group consisting of Nb, Sb, Ta, and W, and

a, b, x, y, and z represent 0≤a≤0.10, 0≤b≤0.05, 0.05≤x≤0.58, 0.05≤y≤0.62, and 0≤z≤0.02, respectively.

Specifically, the piezoelectric single crystal is a piezoelectric single crystal (a=0, and b=0) having a perovskite type crystal structure ([A][B]O₃) comprising zirconium (Zr), and examples thereof include [Pb_{(1-a-b)}SrₐBa_{b}][(mg, Zn)_{1/3}Nb_{2/3})_{(1-x-y)}TiₓZr_{y}]O₃, [Pb][(Mg₁₋ₐZnₐ)_{1/3}Nb_{2/3})_{(1-x-y)}TiₓZr_{y}]O₃, [Pb][(Mg_{1/3}Nb_{2/3})_{(1-x-y)}TiₓZr_{y}]O₃, and [BaₓBi₍₁₋ₓ₎][Fe₍₁₋ₓ₎Ti_{(x-y)}Zr_{y}]O₃.

Also, the present invention comprises a piezoelectric single crystal capable of realizing uniformity and improving piezoelectric characteristics without a composition gradient even in case of complex, chemical composition thanks to a solid phase single crystal growth method, and specifically, dielectric characteristics of a high dielectric constant K3T, high piezoelectric constants d₃₃ and k₃₃, high phase transition temperatures T_{C} and T_{RT}, a high coercive electric field E_{C} are improved by complex composition (a≠0, and b≠0) of ions located at [A] from a perovskite type crystal structure (A][B]O₃).

Accordingly, with respect to the piezoelectric single crystal represented by the compositional formula of Chemical Formula 1, specifically reviewing the complex composition of the ions located at [A], the complex composition may be constituted in [A_{1-(a+1.5b)}BₐC_{b}], composition of said A comprises a flexible or inflexible element, and in the examples of the present invention, although the piezoelectric single crystal is describes in a state of being limited to a piezoelectric single crystal in flexible series in which A represents Pb, it should not be limited thereto.

With respect to the ions located at said [A], composition of B is a metal dyad, preferably, at least one or more elements selected from a group consisting of Ba, Ca, Co, Fe, Ni, Sn, and Sr, and a metal triad is used in composition of C.

It is preferable to use one or more elements selected from a group consisting of Co, Fe, Bi, La, Ce, Pr, Nd, Pm, Sm, Eu, Gd, Tb, Dy, Ho, Er, Tm, Yb, and Lu, and it is more preferable to use a single form composed of one element in lanthanide series, or a mixed form in which two elements in lanthanide series are.

In the example of the present invention, with respect to the ions located at [A], although it is described that the composition of C is composition in which Sm is included alone, or composition in which two elements are mixed, it should not be limited thereto.

With respect to the complex composition of the ions located at [A] from the piezoelectric single crystal represented by the compositional formula of said Chemical Formula 1 or Chemical Formula 2, the composition of [A_{1-(a+1.5b)}BₐC_{b}] corresponding to the ions located at [A] is a requisite for realizing a targeted physical property, and when A is a flexible or inflexible piezoelectric single crystal, it is characteristic in that the complex composition is composed by mixing of a metal dyad and a metal triad.

In said formula, a requisite of 0.01≤a≤0.10, and a requisite of 0.01≤b≤0.05 are satisfied, and in particular, in said formula, a requisite of a/b≥2 is satisfied. At this time, when a is less than 0.01, this is problematic in that a perovskite phase is unstable, and when a exceeds 0.10, a phase transition temperature gets too low, so it is not preferable due to difficulty in practical use.

Also, when no requisite of a/b≥2 is satisfied, this is not preferable because it is problematic in that dielectric and piezoelectric characteristics are not maximized, or growth of the single crystal is limited. At this time, with respect to the complex composition of the ions located at [A] from the piezoelectric single crystal represented by the compositional formula of Chemical Formula 1, in case of the complex composition, an excellent dielectric constant beyond that shown in case of composition in which a metal triad, or a metal dyad is composed alone may be realized.

In said Chemical Formula 1, it is preferable that x belongs into a range of 0.05≤x≤0.58, and more preferably, 0.10≤x≤0.58. At this time, the reason is that phase transition temperatures T_{C} and T_{RT} are low, piezoelectric constants d₃₃ and k₃₃ are low, or a coercive electric field E_{C} is low in case that x is less than 0.05, and a dielectric constant K₃^{T} is low, piezoelectric constants d₃₃ and k₃₃ are low, or a phase transition temperature T_{RT} is low in case that x exceeds 0.58. Meanwhile, it is preferable that y belongs into a range of 0.050≤y≤0.62, more preferably satisfying a requisite of 0.10≤y≤0.62. The reason is that phase transition temperatures T_{C} and T_{RT} are low, piezoelectric constants d₃₃ and k₃₃ are low, or a coercive electric field E_{C} is low in case that y is less than 0.05, and a dielectric constant K₃^{T} is low, or piezoelectric constants d₃₃ and k₃₃ are low in case that y exceeds 0.62.

The piezoelectric single crystal represented by the compositional formula of Chemical Formula 1 according to the present invention comprises a metal tetrad in ions located at [B], and in particular, concerning composition of L, it is limited to a single form composed of one selected from Zr or Hf, or a mixed form thereof.

When L represents a mixed form, a piezoelectric single crystal represented by a compositional formula of Chemical Formula 2 below or Chemical Formula 2 below is provided:

[A_{1-(a+1.5b)}BₐC_{b}][(MN)_{1-x-y}(Zr_{1-w},Hf_{w})_{y}Tiₓ]O₃ Chemical Formula 2

[A_{1-(a+1.5b)}BₐC_{b}][(MN)_{1-x-y}(Zr_{1-w},Hf_{w})_{y}Tiₓ]O_{3-z} Chemical Formula 3

in said formulae, A, B, C, M, N, a, b, x, y, and z are the same as those shown in said Chemical Formula 1, but w represents a requisite of 0.01≤w≤0.20.

At this time, when said w is less than 0.01, it is problematic in that dielectric and piezoelectric characteristics are not maximized, and when said w exceeds 0.20, it isn't preferable in that dielectric and piezoelectric characteristics decrease suddenly.

The piezoelectric single crystal represented by the compositional formula of said Chemical Formula 2 or said Chemical Formula 3 as described above is a piezoelectric single crystal in which complex composition of the ions located at [A], and composition of the ions located at [B] from the perovskite type crystal structure ([A][B]O₃) are mixed so that a curie temperature T_{C} is 180° C. or more, and at the same time as this, a phase transition temperature T_{RT} between a rhombohedral phase and a tetragonal phase is 100° C. or more. At this time, when the curie temperature is less than 180° C., this is problematic in that it is difficult to raise a coercive electric field E_{C} up to 5 kV/cm or more, or the phase transition temperature T_{RT} up to 100° C. or more.

Also, the piezoelectric single crystal represented by the compositional formula of Chemical Formula 1 is characteristic in that oxygen vacancy located at [O] from the perovskite type crystal structure ([A][B]O₃) is controlled based on the requisite of 0≤z≤0.02. At this time, when said z exceeds 0.02, this is preferable because it is problematic in that the dielectric and piezoelectric characteristics decrease suddenly.

When the oxygen vacancy is induced into the range, a coercive electric field and an internal electric field increase effectively, so stability of the piezoelectric single crystal increases at the time of driving of the electric field, and under a condition of mechanical load. Accordingly, the piezoelectric characteristics are maximized, and at the same time as this, stability is also able to be enhanced.

The piezoelectric single crystal represented by the compositional formula of said Chemical Formula 1 according to the present invention shows that an electromechanical coupling coefficient k₃₃ is 0.85 or more, and when the electromechanical coupling coefficient is less than 0.85, this is not preferable in that characteristics shown in the piezoelectric single crystal are similar to those shown in piezoelectric polycrystalline ceramic, and energy conversion efficiency gets low.

With respect to the piezoelectric single crystal according to the present invention, it is preferable that the coercive electric field E_{C} is 4 to 12 kV/cm, and when the coercive electric field is less than 4 kV/cm, this is problematic in that poling is easily removed at the time of processing of the piezoelectric single crystal, or at the time of manufacturing or using of components to which the piezoelectric single crystal is applied.

Also, the piezoelectric single crystal represented by the compositional formula of Chemical Formula 1 according to the present invention may be provided in a single crystal having uniformity because a composition gradient inside of the single crystal is formed in a range of 0.2 to 0.5 mol %.

Since lead zirconate (PbZrO₃) has 230° C. of a high phase transition temperature, and is also effective to cause the morphotropic phase boundary (MPB) to be more perpendicular to a temperature axis, it enables a high phase transition temperature T_{RT} between the rhombohedral phase and the tetragonal phase to be obtained while causing a high curie temperature to be maintained, so composition which causes phase transition temperatures T_{c} and T_{RT} to be high simultaneously may be developed.

That is because the phase transition temperatures increase in proportion to a content of the lead zirconate even in case that the lead zirconate is mixed into conventional piezoelectric single crystal composition. Accordingly, the piezoelectric single crystal with the perovskite type crystal structure comprising zirconium (Zr) or lead zirconate may overcome problems occurring from existing piezoelectric single crystals. Also, zirconia (ZrO2) or lead zirconate is used in main ingredients from existing piezoelectric polycrystal materials, and is able to make the objects of the present invention accomplished without an increase in raw material costs because they are low-priced raw materials.

On the contrary, unlike PMN-PT, PZN-PT, and so on, the perovskite type piezoelectric single crystal comprising lead zirconate doesn't show a congruent melting behavior at the time of melting, but shows an incongruent melting behavior. Accordingly, when the piezoelectric single crystal shows the incongruent melting behavior, it is divided into liquid phase zirconia and solid phase zirconia (ZrO₂) at the time of melting of a solid phase, and it may not be manufactured by a flux method, Bridgman method, and so on which are general single crystal growth methods using a melting process because solid phase zirconia particles inside of a liquid phase interrupts growth of the single crystal.

Also, it is difficult to manufacture a single crystal comprising a reinforced second phase through the general single crystal growth methods using a melting process, and it has never been reported yet to manufacture the single crystal. That is because a reinforced second phase reacts to a liquid phase due to its chemical instability at a melting temperature or more, and the reinforced second phase is thus removed without being maintained in an individual second phase form. Also, since a separation between the second phase and the liquid phase occurs due to a difference in density between the second phase within the liquid phase, and the liquid phase, it is difficult to manufacture a single crystal comprising the second phase, and also, volume fraction, a size, a shape, arrangement, distribution, and so on of the reinforced second phase inside of the single crystal may not be controlled.

Thus, according to the present invention, piezoelectric single crystals comprising a reinforced second phase are manufactured using a solid phase single crystal growth method in which no melting process is used. In the solid phase single crystal growth method, single crystal growth occurs at a melting temperature or below, so a chemical reaction between the reinforced second phase and the single crystal is controlled, and the reinforced second phase becomes to exist stably in an individual form inside of the single crystal.

The reinforced second phase may be one or more materials selected from a group consisting of a metal phase (e.g., Au, Ag, Ir, Pt, Pd, or Rh), an oxide phase (e.g., MgO or ZrO₂), and a pore.

Also, single crystal growth occurs from a polycrystal comprising the reinforced second phase, and there is no change in the volume fraction, size, shape, arrangement, distribution, and so on of the reinforced second phase during the single crystal growth. Accordingly, when the volume fraction, size, shape, arrangement, distribution, and so on of the reinforced second phase inside of the polycrystal are controlled in a process of making the polycrystal comprising the reinforced second phase, and the single crystals are grown, as a result thereof, the single crystals comprising the reinforced second phase in a desired form, namely, reinforced piezoelectric single crystals (second phase-reinforced single crystals) may be manufactured. As can be seen from the fact that the reinforced second phase P is uniformly distributed in a particle form, or the reinforce second phase is regularly distributed while having a fixed pattern, the feature which shows that the dielectric, piezoelectric, and mechanical characteristics are improved according to a distribution form of the second phase may be realized.

Accordingly, with respect to the present invention, since the perovskite type piezoelectric single crystal comprising lead zirconate is provided by the solid phase single crystal growth method, the cost of production for the single crystal may be reduced by a general heat treatment process without need for a special device, and mass production may be realized at a lower process cost compared with that incurred from a conventional flux method, and Bridgman method.

Also, according to the present invention, thanks to the solid phase single crystal growth method, with respect to the perovskite type crystal structure ([A][B]O₃) comprising lead zirconate, although complicated composition is formed by mixing of complex composition of the ions located at [A], and composition of the ions located at [B], the piezoelectric single crystal is uniformly grown, so the novel piezoelectric single crystal showing a dielectric constant (K3T=6,000 to 15,000), a piezoelectric constant (d₃₃=1,000 to 6,000pC/N), and a dielectric loss (tan δ<2%) which are remarkably improved beyond those shown in conventional piezoelectric single crystals may be provided.

The electric field-vibration generating transducer in which the piezoelectric single crystal having the dielectric and piezoelectric characteristics as described above is used in a dielectric material radiates an electric field and a mechanical vibration simultaneously as a size and a shape of the piezoelectric material, and a frequency and intensity of input voltage are controlled. At this time, (1) a frequency of the electric field radiated ranges from 0.01 Hz to 500 kHz, and intensity of the electric field radiated ranges from 0.01 V/cm to 100 V/cm, and (2) a frequency of the mechanical vibration radiated ranges from 0.1 Hz to 3 MHz, and magnitude of the mechanical vibration radiated satisfies a range which reaches a maximum of 1%.

(2) Polymer-Piezoelectric Composite

FIG. 2 illustrates a case in which the electric field-vibration generating transducer according to the present invention is applied into a medical device.

The electric field-vibration generating transducer 10 according to the present invention comprises: a dielectric material 11 having a dielectric characteristic; an external electrode 12 configured to cause an electric field to be applied to the dielectric material; and a voltage supply device 20 configured to cause voltage to be applied to the external electrode. The dielectric material 11 is connected to the external electrode 12 via an electrical connection line 21, and the external electrode is connected to the voltage supply device 20 so that an electrical signal is applied to the dielectric material. At this time, the electric field-vibration generating transducer may be attached to a bodily part 30, like the head, the skin, or the like, namely, a plurality of electric field-vibration generating transducers may be attached to bodily parts in the neighborhood of a region in which a target tumor is located.

Thanks to the dielectric characteristics shown in the dielectric material, like the low dielectric loss (tan δ<2%) simultaneously with the high piezoelectric constant (d₃₃=1,000 to 6,000 pC/N), and the high dielectric constant (K₃^{T}=6,000 to 15,000), when the voltage is applied, the electric field and the mechanical vibration are radiated simultaneously, so an effect of treatment may be maximized, and an effect of massage caused by the mechanical vibration may be provided. At this time, since the electric field-vibration generating transducer should be applied to a curved surface rather than being attached to a flat surface, it is required to have flexibility.

Thus, with respect to the electric field-vibration generating transducer according to the present invention, a polymer-piezoelectric composite is used in the piezoelectric material so that the electric field-vibration generating transducer can be provided with flexibility.

The polymer-piezoelectric composite shows that a polymer matrix is comprising a range of 10 to 80 vol %, wherein the commercial products of epoxy materials (Epotek Epoxies 301 and 301-2) may be used in the polymer, and since the epoxy materials have low viscosity compared with that of water, they percolate through a crack or a gap naturally, and are cured without relations with whether or not to provide heat so that a strong combination can be provided, and this characteristic is applied to glass, ceramic, quartz, and metal as well as most plastic. Accordingly, as the polymer is used in the polymer-piezoelectric composite, flexibility caused by the strong combination may be provided.

The polymer-piezoelectric composite is a 1-3 type or 2-2 type composite structure in which a rod-type piezoelectric material is embedded in the polymer matrix, wherein the piezoelectric composite may have competitiveness in price in such a manner as to cause an amount in use of the piezoelectric single crystal to be reduced because the piezoelectric polycrystalline ceramic material is mixed in the piezoelectric single crystal satisfying the piezoelectric characteristic.

At this time, examples of the material to be mixed in the piezoelectric single crystal according to the present invention may include publicly known piezoelectric single crystals showing low performance compared with that shown in the piezoelectric single crystal according to the present invention as well as polycrystalline ceramic based on BaTiO₃, PZT, PMN, and PMN-PT.

As one example thereof, a piezoelectric single crystal having the advantages of showing high dielectric and piezoelectric characteristics (K₃^{T}>4,000, d₃₃>1,400 pC/N, and k₃₃>0.85) at the normal temperature, but having the defects of a low coercive field E_{C} and brittleness may be used. Specifically, PMN-PT (Pb(Mg_{1/3}Nb_{2/3})O₃—PbTiO₃), PZN-PT (Pb(Zn_{1/3}Nb_{2/3})O₃—PbTiO₃) PInN-PT (Pb(In_{1/2}Nb_{1/2})O₃—PbTiO₃) PYbN-PT (Pb(Yb_{1/2}Nb_{1/2})O₃—PbTiO₃), PSN-PT (Pb(Sc_{1/2}Nb_{1/2})O₃—PbTiO₃), PMN-PInN-PT, PMN-PYbN-PT, BiScO₃—PbTiO₃ (BS-PT), and so on are included.

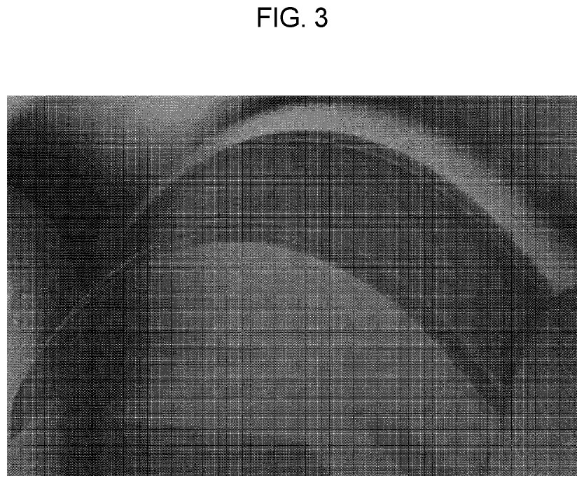

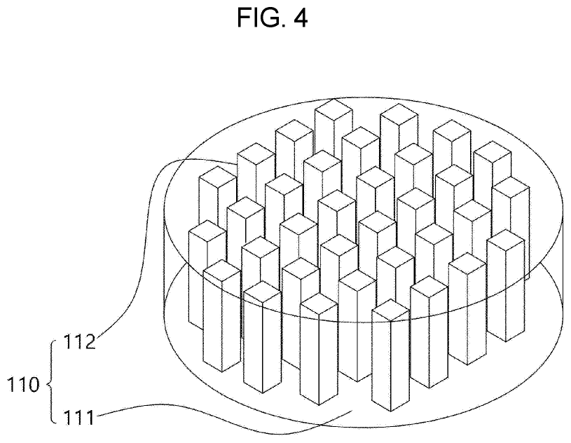

FIG. 3 shows a result of evaluating bending concerning the polymer-piezoelectric composite according to the present invention, wherein flexibility may be confirmed, and FIG. 4 is a schematic diagram showing a structure of the polymer-piezoelectric composite 110, a composite (1-3 type composite) structure which shows that the rod-type piezoelectric materials 112 resulting from cutting a single crystal are inherent in the polymer matrix 111.

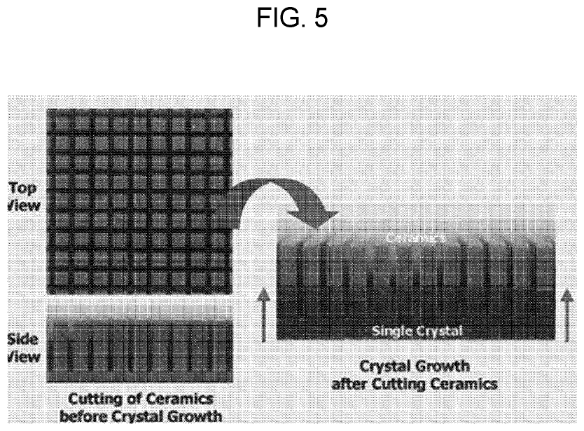

FIG. 5 shows photos concerning the 1-3 type composite structure according to the present invention, wherein a top view photo and a side view photo on the left of the drawing result from cutting polycrystalline ceramic in width x depth dimensions, and as shown in the illustrated photo on the right, the structure may be completed in such a manner as to fill the single crystal, which is crystal-grown, with a polymer, and to carry out curing after carrying out said cutting. This method is more economical than cutting the single crystal right away, and is profitable to mass production.

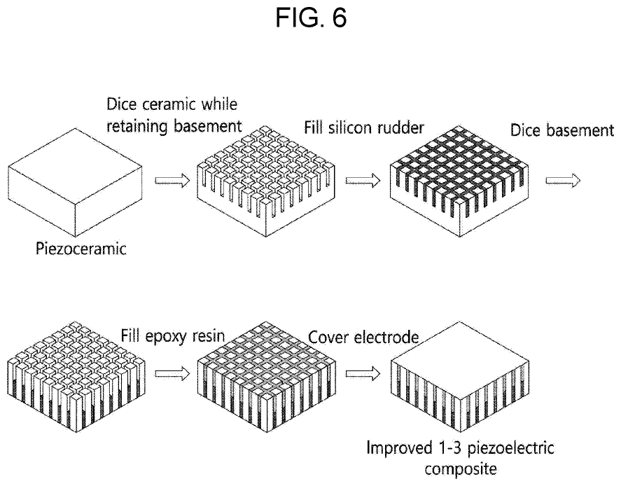

FIG. 6 illustrates, by steps, a process of manufacturing an electric field-vibration generating transducer using the polymer-piezoelectric composite.

Furthermore, the present invention provides a method of manufacturing an electric field-vibration generating transducer, the method comprising: processing a piezoelectric material having a perovskite type crystal structure ([A][B]O₃) in a thickness of 0.1 to 100 mm; forming each external electrode on both surfaces of the piezoelectric material; causing voltage to be applied to the external electrode so as to carry out poling, thereby maximizing dielectric and piezoelectric characteristics of the piezoelectric material; and partly or totally removing any one of the external electrodes formed on said both surfaces, thereby forming an asymmetrical structure.

In the piezoelectric material may be used a piezoelectric single crystal having a perovskite type crystal structure ([A][B]O₃), or a polymer-piezoelectric composite comprising the piezoelectric single crystal. Since the detailed description thereof is identical with that previously described, it is omitted.

The thickness of the piezoelectric material at the time of processing is decided according to magnitude and a frequency of a vibration, preferably, the thickness is 0.1 to 100 mm. At this time, when the thickness is less than 0.1 mm, magnitude of an electric field and magnitude of the vibration get too small, so the piezoelectric material is restricted in practical effect, and when the thickness exceeds 100 mm, a level of voltage which induces the electric field and the vibration gets too large, so it is problematic in that the piezoelectric material is restricted in practical use.

The electric field-vibration generating transducer manufactured by the manufacturing method satisfies as follows: (1) a frequency of the electric field radiated ranges from 0.01 Hz to 500 kHz, and intensity of the electric field radiated ranges from 0.01 V/cm to 100 V/cm; and (2) a frequency of the mechanical vibration radiated ranges from 0.1 Hz to 3 MHz, and magnitude of the mechanical vibration ranges as a maximum of 1%.

The frequency and the magnitude of the mechanical vibration radiated from the electric field-vibration generating transducer may be controlled using a method of controlling a size, and a shape of the piezoelectric material, and a frequency and intensity of input voltage.

With respect to the electric field-vibration generating transducer as described above, since the piezoelectric material of a high degree of displacement is used, when voltage is applied to the piezoelectric material, the electric field-vibration generating transducer may generate mechanical displacement and a mechanical vibration, may accelerate the movement of a material, a chemical action, a biological reaction using the electric field and the mechanical vibration, and may be applied to a medical device for the purpose of treatment for tumors aimed at human bodies and animals.

In particular, in case that the electric field-vibration generating transducer is applied to a medical device, it may be attached to a lot of uneven parts from the skin or scalp, and the electric field-vibration generating transducer will be useful in bringing about an effect of massage and breathing of the skin.

### MODE FOR CARRYING OUT THE INVENTION

Hereinafter, the present invention is described in more detail on the basis of the examples.

The present examples are intended for describing the present invention more specifically, and the scope of the present invention should not be construed as being limited to these examples.

### <Example 1> Production 1 of an Electric Field-Vibration Generating Transducer Using a Piezoelectric Single Crystal

A piezoelectric single crystal of composition of [Pb][(Mg_{1/3}Nb_{2/3})_{0.4}Zr_{0.26}Ti_{0.34}]O₃ was produced by a solid phase single crystal growth method. Also, an excess of quantity of Mgo was added in a synthetic process of powder so that a second phase of MgO, and a pore reinforcement phase were included in the range of 2 vol % inside of the single crystal produced. At this time, as a result of evaluating characteristics of a piezoelectric constant, a dielectric constant, and a dielectric loss of the single crystal produced, the piezoelectric constant d₃₃ was 2,007 pC/N, the dielectric constant was 6,560, and the dielectric loss tan δ was 0.9%.

An electric field-vibration generating transducer in a disk-like shape [20 (L)×20 (L)×1 (T) mm] was produced in such a manner as to cut the produced piezoelectric single crystal in (001) plane, to coat both surfaces with an Ag paste electrode, to remove the Ag electrode from one surface after poling, and to carry out cutting.

With respect to the electric field-vibration generating transducer produced as described above, intensity (magnitude) of an electric field radiated, and displacement of a mechanical vibration were measured as described in Table 1 below.

TABLE 1
Characteristics of a Radiated Electric Field and Displacement
of the Electric Field-Vibration Generating Transducer
Using the Piezoelectric Single Crystal

| Voltage [kV] | Electric Field [V/cm] | Displacement [%] |
|---|---|---|
| 0.2 | 9 | 0.016 |
| 0.4 | 22 | 0.036 |
| 0.6 | 31 | 0.058 |
| 0.8 | 38 | 0.075 |
| 1.0 | 52 | 0.104 |

As confirmed from the result, the electric field-vibration generating transducer using the piezoelectric single crystal of the composition of [Pb][(Mg_{1/3}Nb_{2/3})_{0.4}Zr_{0.26}Ti_{0.34}]O₃ showed that the electric field and the displacement (vibration) which came up to the standard of practicable application were induced.

### <Example 2> Production 2 of an Electric Field-Vibration Generating Transducer Using a Piezoelectric Single Crystal

An electric field-vibration generating transducer was produced in such a manner as to carry out the same processes as those described in said Example 1 except the fact that a piezoelectric single crystal of composition of [Pb_{0.965}Sr_{0.02}La_{0.01}][(Mg_{1/3}Nb_{2/3})_{0.4}Zr_{0.25}Ti_{0.35}]O₃ was produced by a solid phase single crystal growth method, and was used.

At this time, the piezoelectric single crystal of the composition of [Pb_{0.965}Sr_{0.02}La_{0.01}][(Mg_{1/3}Nb_{2/3})_{0.4}Zr_{0.25}Ti_{0.35}]O₃ showed that a piezoelectric constant d₃₃ was 2,650 pC/N, a dielectric constant was 8,773, and a dielectric loss tan δ was 0.5%.

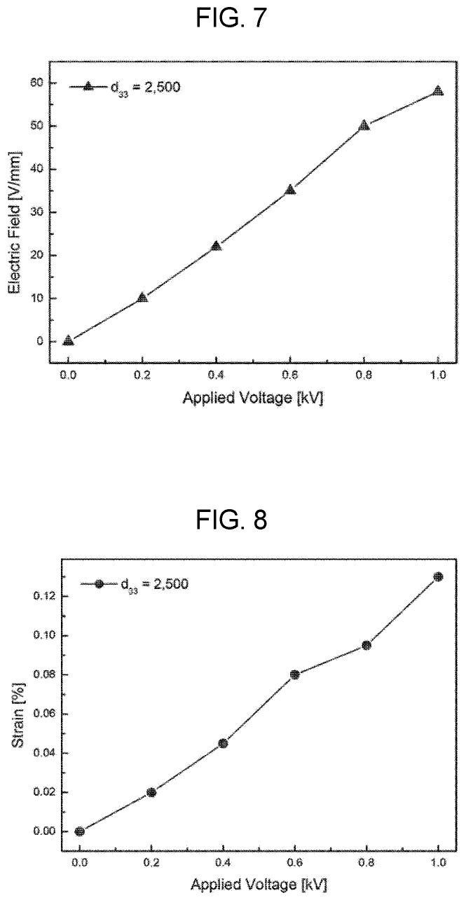

FIG. 7 illustrates intensity of an electric field induced at the time of causing voltage to be applied to the electric field-vibration generating transducer using the piezoelectric single crystal of the composition of [Pb_{0.965}Sr_{0.02}La_{0.01}][(Mg_{1/3}Nb_{2/3})_{0.4}Zr_{0.25}Ti_{0.35}]O₃, and FIG. 8 illustrates magnitude of a mechanical vibration induced at the time of causing voltage to be applied to the same electric field-vibration generating transducer as that shown in FIG. 7.

As confirmed from the result, with respect to the electric field-vibration generating transducer using the piezoelectric single crystal of the composition of [Pb_{0.965}Sr_{0.02}La_{0.01}][(Mg_{1/3}Nb_{2/3})_{0.4}Zr_{0.25}Ti_{0.35}]O₃, as a result of measuring the intensity (magnitude) of the electric field radiated, and the displacement of the mechanical vibration radiated, the electric field and the displacement (vibration) which came up to the standard of practicable application were induced.

### <Example 3> Production 3 of an Electric Field-Vibration Generating Transducer Using a Piezoelectric Single Crystal

A piezoelectric single crystal of composition of [Pb_{0.965}Sr_{0.02}Sm_{0.01}][(Mg_{1/3}Nb_{2/3})_{0.25}(Ni_{1/3}Nb_{2/3})_{0.10}Zr_{0.30}Ti_{0.35}]O₃ was produced by a solid phase single crystal growth method. Also, pores of a matrix phase of a polycrystal were captured inside of the single crystal during growth of the single crystal, and the single crystal produced comprised a pore reinforcement phase of about 1.5 vol %. The produced single crystal showed that a piezoelectric constant d₃₃ was 4,457 pC/N, a dielectric constant was 14,678, and a dielectric loss tan δ was 1.0%.

An electric field-vibration generating transducer in a disk-like shape [20 (L)×20 (L)×1 (T) mm] was produced in such a manner as to cut the piezoelectric single crystal produced in (001) plane, to form an Au electrode on both surfaces of the single crystal using a sputtering process, to remove the Au electrode from one surface after poling, and to carry out cutting.

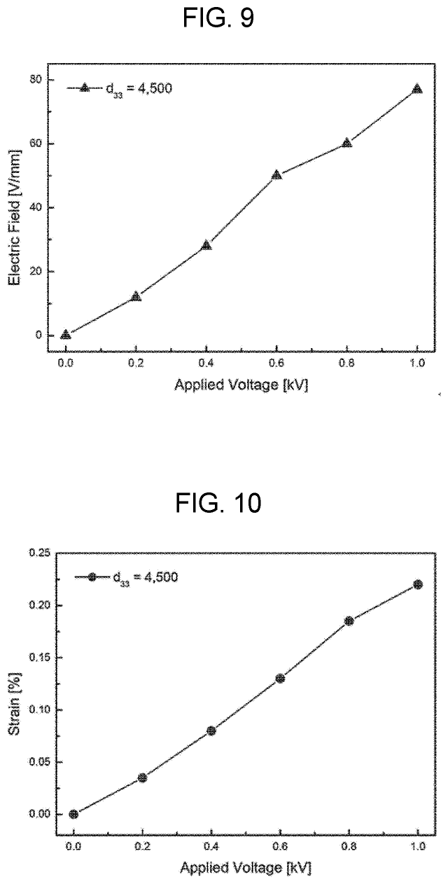

FIG. 9 illustrates intensity of an electric field induced at the time of causing voltage to be applied to the electric field-vibration generating transducer using the piezoelectric single crystal of the composition of [Pb_{0.965}Sr_{0.02}Sm_{0.01}][(Mg_{1/3}Nb_{2/3})_{0.25}(Ni_{1/3}Nb_{2/3})_{0.10}Zr_{0.30}Ti_{0.35}]O₃, and FIG. 10 represents magnitude of a mechanical vibration at the time of causing voltage to be applied.

With respect to the electric field-vibration generating transducer produced as described above, as a result of measuring intensity (magnitude) of the electric field radiated and displacement of the mechanical vibration, it was confirmed that the electric field and the displacement (vibration) which came up to the standard of practicable application were induced.

### <Example 4> Production 4 of an Electric Field-Vibration Generating Transducer Using a Piezoelectric Single Crystal-Epoxy Composite

The piezoelectric single crystal of the composition of [Pb_{0.965}Sr_{0.02}Sm_{0.01}][(Mg_{1/3}Nb_{2/3})_{0.25}(Ni_{1/3}Nb_{2/3})_{0.10}Zr_{0.30}Ti_{0.35}]O₃ shown in said Example 3 showed that the piezoelectric constant d₃₃ was 4,457 pC/N, the dielectric constant was 14,678, and the dielectric loss tan δ was 1.0%, and had the disk-like shape, and a 1-3 type composite was produced in such a manner as to cut the piezoelectric single crystal in the disk-like shape using a dicing process, and to pour an epoxy resin (Epotek 301, Epoxy Technology Inc. (U.S.A.)) on the cut parts of the single crystal at a volume ratio of 1 to 1, and to carry out curing.

An electric field-vibration generating transducer using the composite in the disk-like shape [20 (L)×20 (L)×1 (T) mm] was produced in such a manner as to form an Au electrode on both surfaces [(001) plane] of the composite using a sputtering process, to remove the Au electrode from one surface after poling, and to carry out cutting.

With respect to the electric field-vibration generating transducer using the composite produced as described above, a result of measuring intensity (magnitude) of an electric field radiated, and displacement of a mechanical vibration radiated was described in Table 2.

TABLE 2
Characteristics of a Radiated Electric Field and Displacement
of the Electric Field-Vibration Generating Transducer Using
the Piezoelectric Single Crystal-Epoxy Composite

| Voltage [kV] | Electric Field [V/cm] | Displacement [%] |
|---|---|---|
| 0.2 | 5 | 0.053 |
| 0.4 | 12 | 0.115 |
| 0.6 | 25 | 0.192 |
| 0.8 | 32 | 0.274 |
| 1.0 | 41 | 0.324 |

With respect to the electric field-vibration generating transducer using the piezoelectric single crystal-epoxy composite produced as describe above, as the result of measuring the intensity (magnitude) of the electric field radiated, and the displacement of the mechanical vibration radiated, a dielectric constant decreased in proportion to an epoxy content inside of the composite compared with that shown in the case in which the piezoelectric single crystal described in Example 3 was used alone (in case of 100%), but the displacement (vibration) increased up to about 50%. Accordingly, the electric field-vibration generating transducer using the composite was confirmed to show characteristics of flexibility, improved resistance to fracture, and improved displacement (vibration).

Accordingly, the electric field-vibration generating transducer using the piezoelectric single crystal, which satisfies the dielectric and piezoelectric characteristics, in a dielectric material may accelerate the movement of a material, a chemical action, and a biological reaction, and may be applied to a medical device for the purpose of treatment for tumors aimed at human bodies and animals.

As previously described, although the present invention has been described in detail on the basis of only the detailed examples as described, it should be obvious that various variations and modifications can be made by those having ordinary skill in the art within the scope of the technical idea of the present invention, and it should be natural that these variations and modifications belong into the scope of the accompanying claims.

### DESCRIPTION OF REFERENCE NUMERALS

10: Electric Field-Vibration Generating Transducer
11: Piezoelectric Material
12: Electrode
20: Voltage Supply Device
21: Electrical Connection Line
30: Skin
40: Tissue 41: Tumor
42: Electric Field
110: Polymer-Piezoelectric Composite
111: polymer
112: Piezoelectric Composite

What is claimed is:

1. An electric field-vibration generating transducer, which radiates an electric field and a mechanical vibration simultaneously, comprising:
a piezoelectric material having a perovskite type crystal structure ([A][B]O₃); and
an electrode formed on at least one surface of the piezoelectric material,
wherein it is satisfied that a piezoelectric constant d₃₃ of the piezoelectric material is 1,000 to 6,000 pC/N,
a dielectric constant K₃^{T} of the piezoelectric material is 6,000 to 15,000, and
a dielectric loss of the piezoelectric material is 2% or below.

2. The transducer of claim 1, wherein when the electrode is formed only on any one surface of the piezoelectric material, or the electrode is formed on both surfaces of the piezoelectric material, a material, a shape, or an area of the electrode are formed asymmetrically.

3. The transducer of claim 1, wherein the piezoelectric material is a piezoelectric single crystal having a perovskite type crystal structure ([A][B]O₃), or a polymer-piezoelectric composite comprising the piezoelectric single crystal.

4. The transducer of claim 3, wherein the piezoelectric single crystal is a piezoelectric single crystal grown by a solid phase single crystal growth method.

5. The transducer of claim 4, wherein the piezoelectric single crystal is expressed by a compositional formula of Chemical Formula 1 below:
[A_{1-(a+1.5b)}BₐC_{b}][(MN)_{1-x-y}(L)_{y}Tiₓ]O_{3-z} Chemical Formula 1
in said formula,
A represents one or more elements selected from a group consisting of Pb, Sr, Ba, and Bi
B represents at least one or more elements selected from a group consisting of Ba, Ca, Co, Fe, Ni, Sn, and Sr,
C represents one or more elements selected from a group consisting of Co, Fe, Bi, La, Ce, Pr, Nd, Pm, Sm, Eu, Gd, Tb, Dy, Ho, Er, Tm, Yb, and Lu,
L represents a single form composed of one selected from Zr or Hf, or a mixed form thereof,
M represents at least one or more elements selected from a group consisting of Ce, Co, Fe, In, Mg, Mn, Ni, Sc, Yb, and Zn,
N represents at least one or more elements selected from a group consisting of Nb, Sb, Ta, and W, and
a, b, x, y, and z represent 0≤a≤0.10, 0≤b≤0.05, 0.05≤x≤0.58, 0.05≤y≤0.62, and 0≤z≤0.02, respectively.

6. The transducer of claim 5, wherein in said formula, a requisite of 0.01≤a≤0.10, and a requisite of 0.01≤b≤0.05 are satisfied.

7. The transducer of claim 5, wherein in said formula, a requisite of a/b≥2 is satisfied.

8. The transducer of claim 5, wherein in said formula, a requisite of 0.10≤x≤0.58, and a requisite of 0.10≤y≤0.62 are satisfied.

9. The transducer of claim 5, wherein when L represents a mixed form, the piezoelectric single crystal is expressed by a compositional formula of Chemical Formula 2 or Chemical Formula 3 below:
[A_{1-(a+1.5b)}BₐC_{b}][(MN)_{1-x-y}(Zr_{1-w},Hf_{w})_{y}Tiₓ]O₃ Chemical Formula 2
[A_{1-(a+1.5b)}BₐC_{b}][(MN)_{1-x-y}(Zr_{1-w},Hf_{w})_{y}Tiₓ]O_{3-z} Chemical Formula 3
in said formulae, A, B, C, M, N, a, b, x, y, and z are the same as those shown in said Chemical Formula 1, but w represents 0.01≤w≤0.20.

10. The transducer of claim 5, wherein a 0.1 to 20% reinforced second phase P is further included in the composition of the piezoelectric single crystal at a volume ratio.

11. The transducer of claim 10, wherein the reinforced second phase is a metal phase, an oxide phase, or a pore.

12. The transducer of claim 3, wherein the polymer-piezoelectric composite shows that a polymer matrix is comprising a range of 10 to 80 vol %.

13. The transducer of claim 12, wherein the polymer-piezoelectric composite is a 1-3 type or 2-2 type composite structure in which a rod-type piezoelectric material is embedded in the polymer matrix.

14. The transducer of claim 12, wherein the piezoelectric composite results from mixing piezoelectric polycrystalline ceramic into the piezoelectric single crystal.

15. The transducer of claim 1, wherein a frequency of the electric field radiated is 0.01 Hz to 500 kHz, and intensity of the electric field is 0.01 to 100 V/cm.

16. The transducer of claim 1, wherein a frequency of the mechanical vibration radiated is 0.1 Hz to 3 MHz, and magnitude of the mechanical vibration is 1% or below.

17. The transducer of claim 1, wherein the electrode is any one selected from a group of consisting of conductive metal, carbon, and conductive ceramic.

18. The transducer of claim 1, wherein the piezoelectric material shows that surface unevenness is formed on its surface by pores or grooves.

19. A method of manufacturing an electric field-vibration generating transducer, comprising of:
processing a piezoelectric material having a perovskite type crystal structure ([A][B]O₃) of claim 1 in a thickness of 0.1 to 100 mm;
forming each external electrode on both surfaces of the piezoelectric material;
carrying out poling by causing voltage to be applied to said each external electrode; and
partly or totally removing any one of the external electrodes formed on both surfaces, thereby forming an asymmetric structure.

20. The method of claim 19, wherein the piezoelectric material is a piezoelectric single crystal having a perovskite type crystal structure ([A][B]O₃), or a polymer-piezoelectric composite comprising the piezoelectric single crystal.
